(19) United States
(12) Patent Application Publication
(10) Pub. No.: US 2003/0122175 A1
(43) Pub. Date: Jul. 3, 2003

(54) Integrated passive devices formed by demascene processing

(76) Inventor: Peter Van Buskirk, Newtown, CT (US)

Correspondence Address: INTELLECTUAL PROPERTY / TECHNOLOGY LAW, PO BOX 14329, RESEARCH TRIANGLE PARK, NC, 27709, US

(21) Appl. No.: 10/034,596

(22) Filed: Dec. 28, 2001

(51) Int. Cl. H01L 27/108; H01L 29/76; H01L 29/94; H01L 31/119

(52) U.S. Cl. 257/310

(57) ABSTRACT

A passive transmission line element (device) monolithically integrated into an integrated circuit at one or more levels of the integrated circuit by using a damascene process to delineate a conductive line such that at least the bottom surface and sidewalls of the conductive line are embedded in an enhancement layer having high permeability and/or high permitivity. Optionally a second enhancement layer may cover the conductive line, to completely embed or surround the conductive line with permeability and/or permitivity enhancement material. The passive transmission line device comprising the conductive line and the enhancement layer thus has enhanced distributed inductance and/or enhanced distributed capacitance. In addition, the passive transmission line device may optionally have enhanced distributed resistance as well by forming the conductive line from resistive (i.e., not highly conductive) material.

### TECHNICAL FIELD OF THE INVENTION

The present invention relates generally to microfabrication techniques and integrated devices, to providing passive elements (e.g., resistors, capacitors, and inductors) as conductive lines formed by damascene processing and integrated as part of an integrated circuit, and more particularly to interconnects or conductive lines that have enhanced inductive or capacitive properties by embedding and/or surrounding them in a high permeability or high permitivity material, respectively.

### BACKGROUND OF THE INVENTION

Whereas in the past integrated circuits (IC's) having different circuit functions (e.g., analog, digital, imaging, computing, memory, etc.) were fabricated separately and then connected externally on a circuit board (or by another packaging scheme), there is an accelerating trend towards incorporating multiple circuit functions in a single integrated circuit. This trend is sometimes referred to as being targeted at providing a “system on a chip”, the overarching goal being to provide performance and/or economic advantages. An example of such multi-function, monolithic integration is integrating analog (e.g., neural network) and digital computing functions, along with both non-volatile (e.g., Flash) and volatile (e.g., DRAM) memory.

A variety of semiconductor integrated circuits use passive filtering techniques that employ capacitors, inductors and resistors. In some cases, active filters using those elements are used as well, such as in a circuit that contains an operational amplifier. Yet, despite the trend toward monolithic integration of different IC functions, passive (RLC) elements generally have not been monolithically integrated (on a single-function IC, nor on a multi-function IC) because, in part, there have been no fabrication techniques for providing these elements in a manner that is well suite for such integration. For instance, not only should the fabrication technique advantageously be compatible with processing of other structures present on the IC< but also the passive elements provided should advantageously be compact and easily integrated with the structures and/or devices present on the IC.

It may be appreciated, therefore, that there remains a need for further advancements and improvements in integrating passive elements monolithically, and more particularly in fabricating compact resistive, capacitive, and/or inductive elements directly on a chip during fabrication of other parts of the integrated circuit.

### SUMMARY OF THE INVENTION

The present invention provides such advancements and overcomes the above mentioned problems and other limitations of the background and prior art, by providing at least one passive transmission line element (device) monolithically integrated into an integrated circuit at one or more levels of the integrated circuit by using a damascene process to delineate a conductive line having at least its bottom surface and sidewalls embedded in an enhancement layer having high permitivity and/or high permeability. Optionally a second enhancement layer may cover the conductive line, to completely embed or surround the conductive line with permeability and/or permitivity enhancement material. Thus, the passive transmission line device comprising the conductive line and enhancement layer has enhanced distributed inductance and/or enhanced distributed capacitance. In addition, the passive transmission line device may optionally have enhanced distributed resistance as well by forming the conductive line from a resistive (i.e., not highly conductive) material.

### BRIEF DESCRIPTION OF THE DRAWINGS

For a more complete understanding of the present invention and the advantages thereof, reference is now made to the following description taken in conjunction with the accompanying drawings in which like reference numerals indicate like features and wherein:

Additional aspects, features, and advantages of the invention will be understood and will become more readily apparent when the invention is considered in the light of the following description made in conjunction with the accompanying drawings, wherein:

FIGS. 1A-1H depict schematic cross-sections of an integrated circuit device undergoing a process flow to fabricate an integrated passive transmission line device, in accordance with an illustrative embodiment of the present invention;

FIGS. 2A-2C depict schematic cross-sections of an integrated circuit device undergoing a process flow to fabricate an integrated passive transmission line device, in accordance with another illustrative embodiment of the present invention; and

FIGS. 3A-3C depict schematic cross-sections of an integrated circuit device undergoing a process flow to fabricate an integrated passive transmission line device, in accordance with yet another illustrative embodiment of the present invention.

### DETAILED DESCRIPTION OF THE INVENTION

Preferred embodiments of the present invention are illustrated in the FIGUREs, like numerals being used to refer to like and corresponding parts of the various drawings.

Prior to describing an illustrative embodiment of the present invention, it is noted that the present invention employs fabrication methods (e.g., chemical-mechanical polishing (CMP)) similar to those described in commonly assigned U.S. Pat. No. 5,976,928, entitled “Chemical Mechanical Polishing of FeRAM Capacitors”, which is herein incorporated by reference. U.S. Pat. No. 5,976,928 describes, inter alia, forming a discrete capacitor by using a damascene process to pattern a structure that contains both insulating and conducting materials that comprise the electrodes and the inter-electrode dielectric of the discrete capacitor. Damascene processing refers to redefining conductive lines (e.g., interconnect metalization) by depositing the conductive material into grooves in a dielectric layer and then removing the excess (overfill), typically by chemical-mechanical polishing (CMP). In contrast, other standard metal patterning techniques define a metal pattern by first depositing the metal onto a dielectric and then etching the metal according to a photolithographically defined etch mask formed on the metal. Another patterning technique that may be used in certain applications is liftoff, involves depositing the metal over a photoresist pattern, and then removing the photoresist, leaving metal only where it did not overlay photoresist. In each of these other techniques, photoresist contacts the metal, where as damascene processing avoids such contact.

As will be better understood from the ensuing description, an illustrative embodiment of the present invention employs damascene processing to form a passive device (e.g., resistor, inductor, capacitor) that is in the form of a transmission line (referred to herein as a passive transmission line device/element). As used herein, a transmission line refers to an electrically passive element or structure that carries, conducts, or propagates an electrical signal along a non-insulating/non-dielectric path. Stated differently, a transmission line includes a continuous conductive (i.e., non-insulating) path that is capable of conducting or transmitting an electrical signal. For example, the path may have a high conductivity (e.g., metallic, such as copper, aluminum, various suicides, etc.), or a moderate or low conductivity [e.g., resistive, such as low conductivity metal, metal compound (e.g., TaN, cermet, or various silicides, etc.), polysilicon, etc.]. Transmission line is not used herein to exclude conductive paths other than those that must be treated as a distributed impedance for purposes of network analysis: It embraces a conductive path that may be treated as a lumped impedance, as well as those that must be treated as a distributed impedance.

As will be understood by those skilled in the art, a passive transmission line device according to the present invention conductively couples two nodes of a circuit, and each node may be connected to one or more of a variety of circuit elements or signals, including for example, a terminal of an active device (e.g., a transistor), a terminal of a passive device (e.g., a capacitor, resistor, inductor, or another passive transmission line element according to the present invention), a terminal of a power source (e.g., supply voltage, or ground), or a terminal of a conventional interconnect [i.e., a highly conductive transmission line (line), also referred to in the art as a conductive runner (runner)]. Those skilled in the art5 will also understand that while various implementations of the present invention may appear geometrically similar to a conventional interconnect at least to the extent that they may both include a narrow conductive line, such geomet5ric embodiments of a passive transmission line element according to the present invention nevertheless differ substantially not only structurally but also functionally from a conventional interconnect. As will be better understood from the ensuing description, compared to a conventional highly conductive interconnect, a passive transmission line device according to the present invention has enhanced capacitance (e.g., distributed capacitance, capacitance per unit length) and/or enhanced inductance (e.g., self-inductance, distributed inductance, or inductance per unit length). In combination with the enhanced capacitance and/or enhanced inductance, a passive transmission line device according to the present invention may additionally (optionally) have enhanced resistance (e.g., resistance per unit length). Enhanced inductance is provided by embedding and/or covering the conductive line in a high permeability material. Similarly, embedding and/or covering the conductive line in a high permitivity material provides enhanced capacitance. Using a resistive material for the conductive line provides enhanced resistance.

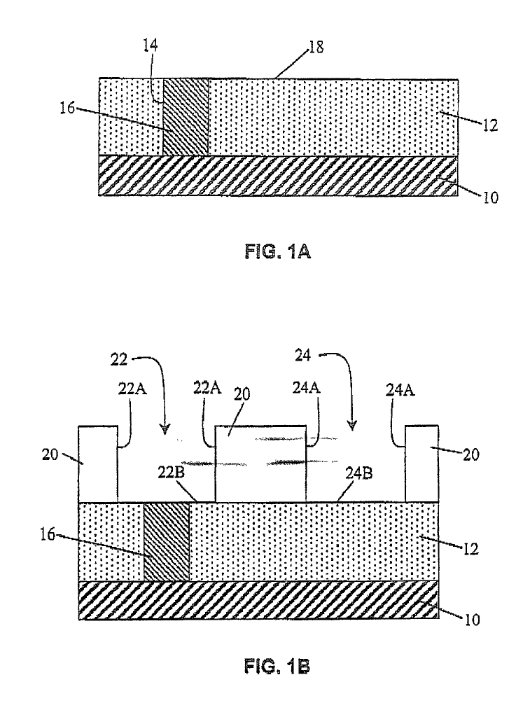

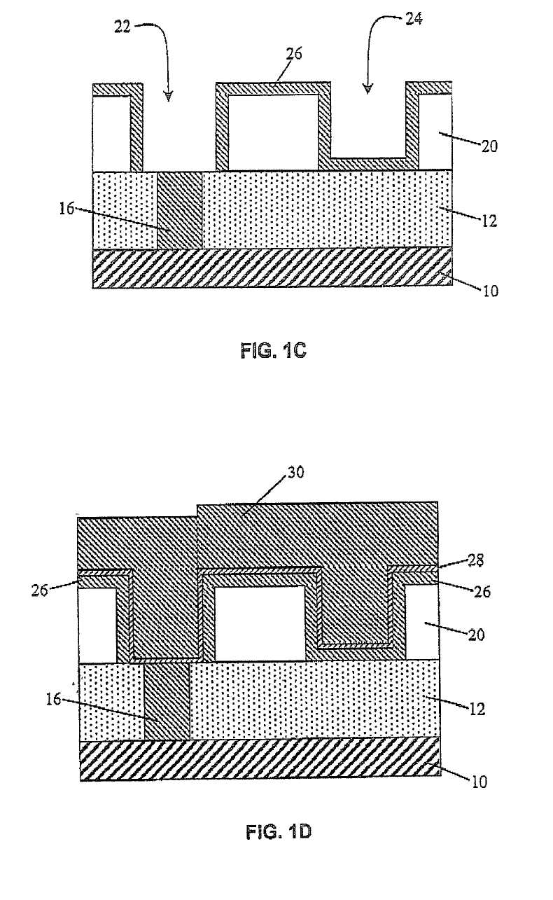

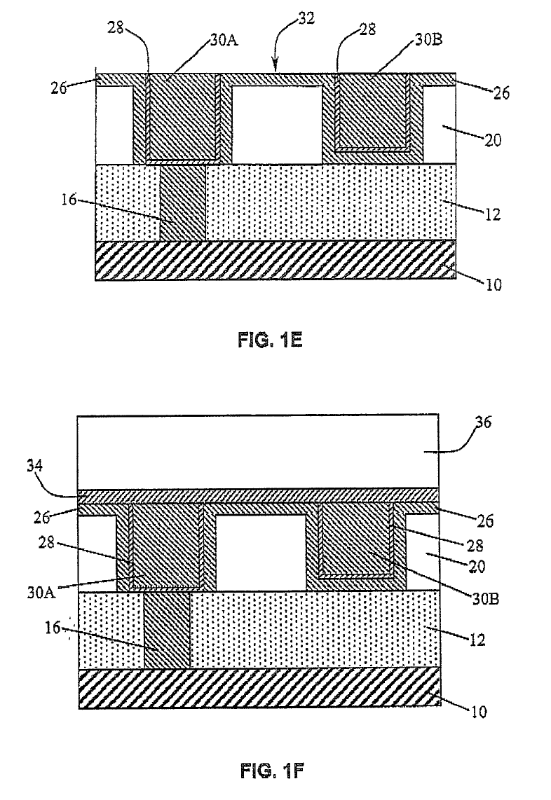

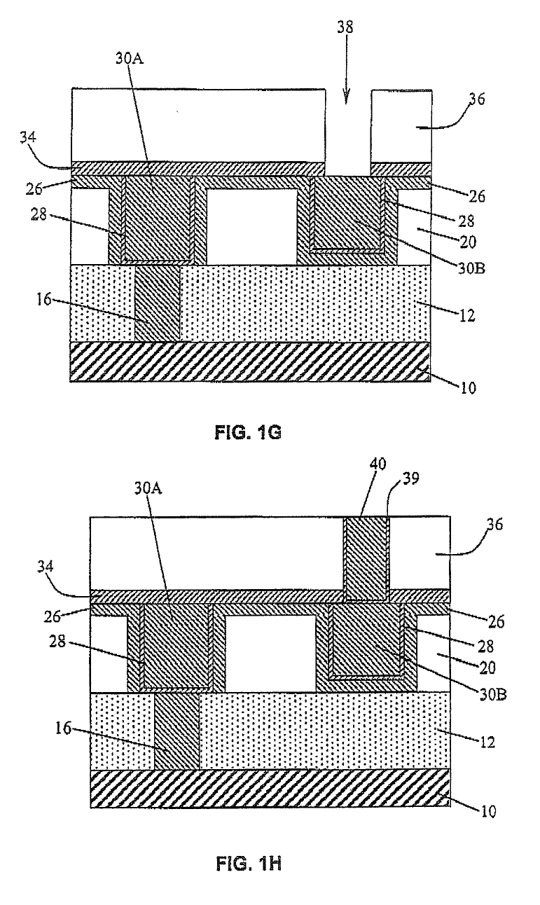

Referring now to FIGS. 1A-1H, there are shown schematic cross-sections of an integrated circuit device undergoing a process flow to fabricate an integrated passive transmission line device, in accordance with an illustrative embodiment of the present invention. As shown in FIG. 1R, fabrication of the passive transmission line device with increased inductance and/or capacitance (and optionally resistance) typically begins with provision of a substrate 10 (e.g., silicon, GaAs, InP, etc.) already containing parts (e.g., transistors and other circuitry, which parts are not shown) of the integrated circuit, although in principle a network of passive transmission line devices may be formed at any time during fabrication of an integrated circuit device. A first insulating layer 12 is provided over the surface of substrate 10, and is patterned by photolithography and etched (e.g., by dry etching, such as plasma etching, reactive ion etching (RIE), etc.) to form a via 14. First insulating layer 12 may be deposited by physical vapor deposition (PVD), chemical vapor deposition (CVD), or spin coating, and may be any of a variety of insulating dielectric (advantageously low dielectric constant) materials such as silicon oxide (e.g., SiO₂, P and/or B doped SiO₂, SiOₓF_{y} where x−y=2, etc.), silicon nitride (Si₃N₄), or various polymers (e.g., polyamide). A conductive plug 16 (which electrically contacts a part of the integrated circuit at the surface of substrate 10) is formed in via 14 by depositing (e.g., by evaporation, sputtering, and/or chemical vapor deposition) at least one conductive material layer (e.g., heavily doped polysilicon, tungsten, etc. and any barrier and/or adhesion layers, such as TiN) over the entire circuit, and then etching back the deposited conductive material layer(s) and optionally also a portion of first insulating layer 12 using dry etching and/or CMP to provide a planarized surface 18.

Upon the structure shown in FIG. 1A, a recess dielectric 20, typically composed of silicon dioxide (i.e., SiO2), silicon nitride (i.e., Si3N4), or another insulator such as those mentioned for first insulating layer 12, is then deposited by standard methods, such as CVD, PVC, or spin coating. Photolithography and wet or dry etching (preferably dry for small feature sizes and high aspect ratios) are then used to define and open recesses (also referred to herein as grooves or trenches) in recess dielectric 20. FIG. 1B shows a recess 22 and a recess 24. Recess 22 has a bottom surface 22B that comprises the top surface of conductive plug 16 and a portion of the top surface of first insulating layer 12 that surrounds plug 16. Recess 24 has a bottom surface 24B that overlies a portion of first insulating layer 12 only. Both recess 22 and 24 have sidewalls 22A and 24A, respectively, formed from first insulating layer 12. As may be appreciated, the recesses extend in the plane perpendicular to the cross-sections depicted in the FIGS. 1A-1H, and the layout of the recesses corresponds to the pathways intended for the passive transmission line devices. Thus, for example, recesses 22 and 24 may represent cross-sectional portions of recesses for two distinct (i.e., not electrically continuous) passive transmission line elements, or for the same (i.e., conductively continuous) passive transmission line element (e.g., the passive transmission line element may be in the form of a loop, coil, or meander).

Referring to FIG. 1C, a first enhancement layer 26 is deposited (e.g., evaporation, sputtering, CVD, laser ablation) over the entire surface (e.g., conformally), including on the top surface of recess dielectric 20, as well as on the bottom surfaces 22B and 24B and sidewalls 22A and 24A of recesses22 and 24. Then, first enhancement layer 26 is removed from the bottom surfaces of recesses that overlie conductive plugs (e.g., recess 22) by photolithography and etching (e.g., dry etching, such as plasma etching, RIE, reactive ion beam etching (RIBE), etc.). First enhancement layer 26 has a high magnetic permeability or a high permitivity (i.e., high relative dielectric constant). Alternatively, enhancement layer 26 may provide both a high magnetic permeability and a high permitivity; for example, enhancement layer 26 may be provided as two separate material layers (and optionally at least one additionally layer, such as an intervening barrier or adhesion layer), one having high permeability and the other having high permitivity.

By way of example, illustrative high permeability materials in accordance with the practicing the present invention include any suitable material having a relative permeability of at least about 2, and advantageously more than about 10. Illustrative high permeability materials include ferrites, which are quaternary (or higher) metal oxide compounds. Ferrites have a wide range of resistivities, for example, from below 10 ohm-cm to cover 1 ohm-cm. Over certain frequency ranges, ferrites exhibit a high real component (u³, which is dispersive, resulting in a phase change for propagating energy) and a low imaginary component (u¹¹, which is dissipative, resulting in a loss of propagating energy) of the complex relative permeability, making them well suited for various applications such as filtering and impedance matching. Examples of ferrites of low u¹¹ in the microwave region include MgMn ferrites (MgₓMn₁₋ₓFe₂O₄) and MgMnAl ferrites (MgₓMn₁₋ₓFe_{2-y}O₄) See e.g., Ceramic Materials for Electronics, R. C. Buchanan, Ed., Marcel Dekker, Inc., New York (1991), Chapter 4. Note that the electrically resistive and magnetic properties of thin films of these materials may be engineered by modifying the grain size, the excess Fe content, the ferromagnetic, paramagnetic phase transition, etc. Certain polycrystalline forms of these materials are expected to display paramagnetic properties, with absence of hysteresis loss, even for compositions and temperatures where ferromagnetic properties are typical in bulk material. Those skilled in the art appreciate that these methods may be used to optimize the ferrite materials based on the application.

Illustrative high permitivity (g) materials that may be used as part of first enhancement layer 26 to provide a passive transmission line device with increased distributed capacitance (capacitance per unit length) include, for example, BaSrTiO₃, paraelectric materials from the PbZrTiO₃ family, TiO₂, Ta₂O₅, etc. By way of example, illustrative high permitivity materials in accordance with the practicing the present invention have a relative dielectric constant of at least about 7 and advantageously more than about 15 or 20 (e.g., compared to low dielectric constant insulators typically used for interlevel dielectrics such as silicon dioxide, silicon nitride, etc., which have relative dielectric constants in the range of less than about 4 to about 7).

Returning now to the process flow, FIG. 1D shows that after the first enhancement layer 26 has been deposited and patterned (as described in connection with FIG. 1C), an optional barrier/adhesion layer 28 and a conductor 30 material are sequentially deposited (e.g., by CVD). Conductor 30 may be Cu, Al, Al/Cu alloys or other high conductivity materials. In an alternative embodiment of the present invention, conductor 30 may be implemented with a low conductivity or resistive material such as TaN or Ta, to provide enhanced resistance per unit length (i.e., it is not highly conductive) for the passive transmission line device (which has enhanced distributed inductance and/or distributed capacitance). As noted, barrier/adhesion layer 28 is optionally provided if needed or desired to provide an improved adhesion and/or a diffusion barrier between first enhancement layer 26 and conductor 30. Illustrative barrier/adhesion layer 28 materials may include, for example, TiN, TiSiN, TiAIN, TiWN, TaN, TaSiN, TaAIN, TaTiN, TaWN, TaW, NbN, ZrN, IrO₂, SiC or any other material suitable to enhance adhesion and/or prevent diffusion or chemical interactions between enhancement layer 26 and conductor 30.

As shown in FIG. BE, the substrate with the deposited films schematically illustrated in FIG. 1D is then planarized to provide upper planar surface 32 by removing excess conductor 30 material and barrier/adhesion layer 28 that lies at an elevation higher than the plane of the uppermost surface of first enhancement layer 26, making the top of conductor 30 coplanar with the uppermost surface of first enhancement layer 26, and thus defining conductive lines 30A and 30B from conductor 30. This removal of the excess conductor 30 and barrier/adhesion layer 28 materials is typically by CMP. Though other dry etching techniques (e.g., plasma etching, RIE, RIBE, etc.) may be employed additionally or exclusively. Thus, conductive lines 30A and 30B embedded in enhancement layer 26 forms a passive transmission line device in accordance with an embodiment of the present invention.

In accordance with a further embodiment of the present invention, conductive lines 30A and 30B may also be covered by a second enhancement layer 34, which is deposited over the planarized surface 32, as depicted in FIG. 1F. As explained for the first enhancement layer 26, second enhancement layer 34 may be a high permeability material only, a high permitivity material only, or a combination of high permitivity and high permeability materials. Illustrative materials are the same as for the first enhancement layer 26. Thus, conductive lines 30A and 30B are completely embedded in (i.e., surrounded by) high permeability and/or high permitivity materials, forming a passive transmission line device in accordance with another embodiment of the present invention. It may be appreciated that second enhancement layer 34 allows for further enhancement of the enhanced permeability and/or enhanced permitivity provided by first enhancement layer 26, by encapsulating the conductive lines. Additionally, where first enhancement layer 26 provides either enhanced inductance or capacitance, exclusively, the provision of second enhancement layer 34 allows for also enhancing the capacitance or inductance, respectively, in a complementary manner. It may further be appreciated that although FIG. 1F schematically shows enhancement layer 34 directly in contact with planarized surface 32, an optional insulating barrier/adhesion layer (e.g., aluminum oxide, silicon nitride, organic adhesion promoter, etc.; not shown) may be deposited therebetween.

In practice, at least one additional interconnect level is typically provided above conductive lines 30A and 30B, and thus FIG. 1F also shows an interlevel dielectric (ILD) 36 deposited (e.g., CVD deposited Sio₂, etc.) over second enhancement layer 34. As shown in FIG. 1G, a via 38 is opened through interlevel dielectric 36 and second enhancement layer 34 to access the top surface of conductive line 30B. Again, dry etching is typically used for etching such via holes, but any appropriate etching method(s) e.g., even wet etching) may be used to etch the materials. Of course, a via may alternatively or additionally be opened to the top surface of conductive line 30A. Also, as is understood, other than the local regions where vias are formed, conductive lines 30A and 30B are completely embedded (i.e., encapsulated) in an enhancement layer material.

FIG. 1H shows a cross-section of the device after forming conductive plugs in the vias. More specifically, first a barrier/adhesion layer 39 material, such as Ta, TaN, TiN, WN or other suitable material, may be deposited (e.g., using CVD or sputtering) over the entire structure of FIG. 1G, and then a metallization for conductive plugs 40 is deposited over that barrier material, conformally filling via 38. The conductive plug 40 metallization may be, for example, CVD-deposited W, or Al that is sputtered at high temperatures or reflowed or Cu, or Al—Cu alloys, or other conductive materials. CMP and/or another suitable etching process (e.g., dry etching) is then used to remove the portion of metallization and barrier/adhesion layer material lying outside the recess (i.e., referred to as the excess or overfill), thus resulting in the structure of FIG. 1H. Alternatively, instead of etching back the deposited metallization and barrier/adhesion layer that overlays ILD 36, these conductive layers may be photolithographically patterned and etched to form an interconnect layer on ILD 36. A yet another alternative implementation, the interconnect level (dielectrics, plugs, and interconnects) above enhancement layer 34 may be fabricated according to a dual-damascene process.

Nevertheless, assuming that plugs are formed as shown in FIG. 1H, a patterned interconnect layer connected to various conductive lines (e.g., conductive line 30B) via the plugs in ILD 36 (e.g., plug 40) may be formed, for example, by depositing interconnect metallization (e.g., a barrier layer such as TiN, followed by Al or an Al—Cu alloy) over the plugs and ILD 36, and then patterning the metallization by photolithography and etching. Alternatively, the interconnect layer may be formed by continuing the process as a single damascene process (i.e., depositing a recess dielectric, opening recesses and vias to the plugs, depositing metallization, CMP). If desired, this subsequent damascene process may be used to define other passive transmission lines in accordance with the present invention.

More generally, as may be appreciated, at least one additional interconnect level may be fabricated above the passive transmission line devices, and depending on design, any of these layers may be a conventional interconnect layer (i.e., without any passive transmission line devices) or an interconnect layer having passive transmission line devices in accordance with the present invention. It is noted that one or more of these interconnect levels may be provided with resistive lines formed by a damascene process using suitable material such as Ta or TaN for the conductive line (which, advantageously, have fairly low temperature coefficient of resistance), but without any surrounding enhancement layer.

As may be appreciated, since both the first and second enhancement layers in the embodiment of FIGS. 1A-1H extend laterally such that they each cover or surround different conductive lines (e.g., conductive lines 30A and 30), both of these layers must generally include an insulating layer to avoid short circuiting conductive lines. Concomitantly, because first enhancement layer 26 generally comprises an insulating material in such an embodiment, it is photolithographically patterned and etched prior to deposition of conductor 30 to remove it from the bottom surfaces of recesses in recess dielectric 20 that overlie conductive plugs (e.g., conductive plug 16) in insulating layer 12, as described above in connection with the fabrication steps to provide the structure of FIG. 1C. This selected removal of the insulating first enhancement layer 26 allows for a good conductive electrical contact (e.g., a low contact resistance ohmic contact) to be formed between conductor 30 and conductive via plug 16.

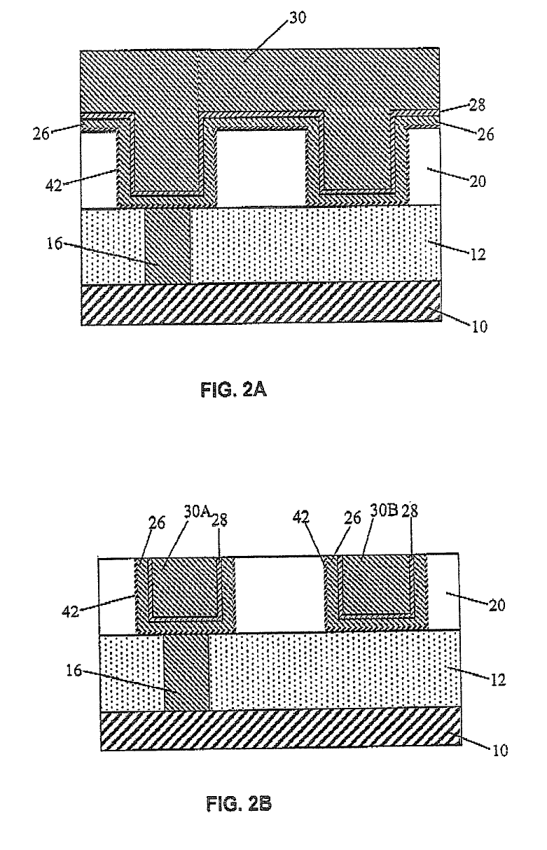

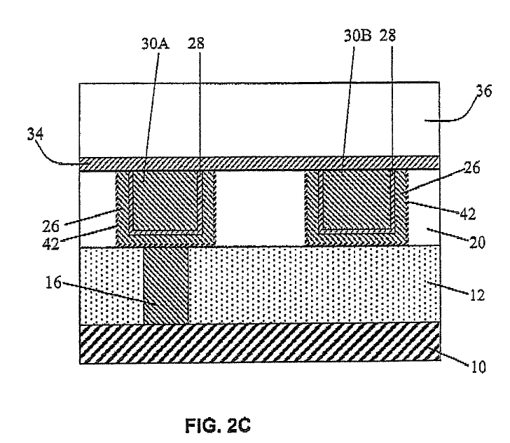

Referring now to FIGS. 2A-2C, there are shown schematic cross-sections after a series of fabrications steps for another illustrative embodiment of the present invention, this embodiment employing a first enhancement layer that is sufficiently conductive that its removal from the bottom of the recesses that overlie a conductive plug is not required to provide a good electrical contact between conductor 30 and via conductive plug 16. Since, however, first enhancement layer 26 is at least somewhat conductive (i.e., it is not highly insulating), it should not extend between or among different conductive lines to avoid current leakage and possible short circuiting. Initially, the basic process flow proceeds similarly to that described in connection with FIGS. 1A and 1B described hereinabove. Thus, beginning with a structure as shown in FIG. 1B, the ensuing process may be outlined as follows:

1. Sequentially deposit optional conductive barrier/adhesion layer 42 (e.g., TiN), first enhancement layer 26, optional barrier/adhesion layer 28, and conductor 30 to provide the structure shown in FIG. 2A.

2. Remove (e.g., by CMP) the portion of conductive barrier/adhesion layer 42, first enhancement layer 26, optional barrier/adhesion layer 28, and conductor 30 that lies outside the recesses (i.e., that is above the plane of the top surface of recess dielectric 20), thus planarizing the top surface of the structure by making conductor 30 coplanar with the top surface of recess dielectric 20. FIG. 2B schematically depicts the resulting structure.

3. Deposit second enhancement layer 34 to completely embed conductive lines 30A and 30B, and then deposit ILD 36 to provide the structure shown in FIG. 2C. Processing may then continue as described above for the illustrative first embodiment, beginning with the steps after providing the structure of FIG. 1F.

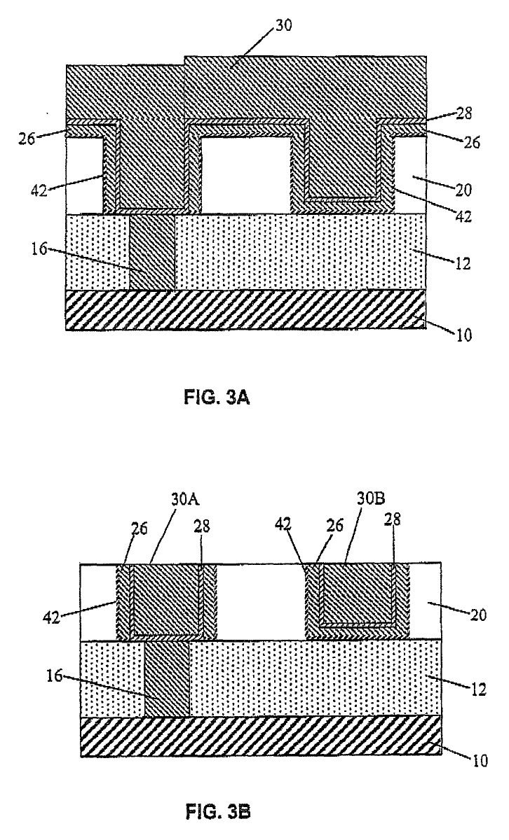

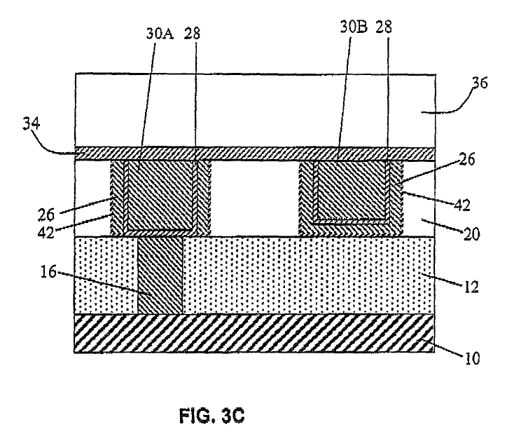

Referring now to FIGS. 3A-3C, there are shown schematic cross-sections after a series of fabrications steps for yet another illustrative embodiment of the present invention. This illustrative embodiment is similar to the latter illustrative embodiment of FIGS. 2A-2C at least to the extent that a planarization (e.g., CMP) step removes, inter alia, the first enhancement layer 26 outside the recesses to prevent any possible shorting between conductive lines in implementations where first enhancement layer may not be highly insulating. Additionally, this illustrative embodiment of FIGS. 3A-3C is also similar to the embodiment of FIGS. 1A-1H at least to the extent that first enhancement layer 26 is photolithographically patterned and etched prior to deposition of conductor 30 to remove it from the bottom surfaces of recesses in recess dielectric 20 that overlie conductive plugs (e.g., conductive plug 16) in insulating layer 12. This removal over the plugs allows for good contact resistance between conductor 30 and plug 16 in implementations where first enhancement layer 26 is highly insulating. Thus, this further illustrative embodiment may employ a first enhancement layer 26 having essentially any conductivity, from highly insulating to highly conductive. Beginning with the structure shown in FIG. 1B, the basic process flow may be outlined as follows:

1. Deposit optional/adhesion layer 42, followed by deposition of first enhancement layer 26.

2. Photolithographically pattern and etch enhancement layer 26 to remove it from the bottom surfaces of the recess in dielectric 20 that overlies conductive plug 16. (At this point, the schematic cross section is similar to that of FIG. 1C, except for the additional, optional barrier/adhesion layer 42).

3. Sequentially deposit optional barrier/adhesion layer 28 and first enhancement layer 256, providing the schematic cross-section of FIG. 3A.

4. Remove (e.g., by CMP) the portion of conductive barrier/adhesion layer 42, first enhancement layer 26, optional barrier/adhesion layer 28, and conductor 3C that lies outside the recesses (i.e., that is above the plane of the top surface of recess dielectric 20), thus planarizing the top surface of the structure by making conductor 30 coplanar with the top surface of recess dielectric 20. FIG. 3B schematically depicts the resulting structure.

5. Deposit second enhancement layer 34 to completely embed conductive lines 30A and 30B, and then deposit ILD 36 to provide the structure shown in FIG. 3C. Processing may then continue as described above for the illustrative first embodiment, beginning with the steps after providing the structure of FIG. 1F.

Accordingly, it may be understood that in accordance with a feature of the present invention, passive elements maybe monolithically integrated into an integrated circuit as passive transmission line elements formed on one or more levels of the integrated circuit by using a damascene process to delineate conductive lines having at least their bottom surfaces and sidewalls embedded in an enhancement layer having high permitivity and/or high permeability. Optionally a second enhancement layer may cover the conductive line, to completely embed or surround the conductive line with permeability and/or permitivity enhancement material. Thus, the passive transmission line devices comprising the conductive lines and enhancement layer have enhanced distributed inductance and/or enhanced distributed capacitance. In addition, they may optionally have enhanced distributed resistance as well by forming the conductive lines from resistive (i.e., not highly conductive) material. Such passive transmission line elements may be interconnected with each other and with other devices to provide, for example, filtering functions, impedance matching, etc.

Those skilled in the art also understand that the specific design of passive transmission line devices (i.e., enhancement layer material(s), layer thicknesses, plan-view topology, etc.) according to the present invention may depend on one or more of many possible factors, including, inter alia, the application of the IC, the function of the passive transmission line device(s), the fabrication technology, and other application and design parameters. For example, while an inductive transmission line device having enhanced distributed inductance according to the present invention may be advantageously employed as a straight line segment for certain applications, other applications may implement the inductive transmission line in a meander or circular geometry (e.g., loop or coil) to provide increased self-inductance. Similarly, if a circular geometry (e.g., loop, coil or spiral topology) is used to implement an inductor or coupled windings as in typical implementations of inductive structures, increased mutual inductance between adjacent windings will be realized if the structure is fabricated embedded in a high permeability material. Additionally, as mentioned, any of one or more levels may have passive transmission line devices, although for clarity the above illustrative embodiments show passive transmission line devices formed on the first interconnect level above the substrate. Further, those skilled in this art understand that there are many variations of the damascene and dual-damascene techniques (e.g., dual-damascene techniques are known to include a variety of via-first and trench-first techniques, with or without an embedded etch stop (hardmask) layer), and the present invention may b advantageously implemented with any such techniques. As mentioned, as used herein, a damascene process may employ etching techniques (e.g., dry etching) other than or in addition to CMP for removing excess/overflow material.

Although the above description of illustrative embodiments of the invention, and of illustrative variations and modifications of such embodiments, provides many specificities, these enabling details should not be construed as limiting the scope of the invention, and it will be readily understood by those persons skilled in the art that the present invention is susceptible to many additional modifications, adaptations, and equivalent implementations without departing from this scope and without diminishing its attendant advantages. It is therefore intended that the present invention is not limited to the disclosed embodiments but should be defined in accordance with the claims, which follow.

We claim:

1. A method of forming a passive transmission line device in an integrated circuit, the method comprising:
Forming a recess insulating layer having a top surface and a bottom surface;
Forming a recess in said recess insulating layer, said recess having walls and a bottom surface;
Forming an enhancement layer covering said walls and said bottom surface of said recess, said enhancement layer having substantial magnetic permeability or substantial dielectric permitivity or both substantial magnetic permeability and substantial dielectric permitivity; and
Forming a conductive line over said enhancement layer in said recess, said conductive line having an upper surface that does not extend laterally outside said recess.

2. The method according to claim 1, wherein the upper surface of said conductive line is substantially coplanar with said upper surface of said first insulating layer.

3. The method according to claim 1, wherein the upper surface of said conductive line is substantially coplanar with an upper surface of said enhancement layer for portions of said enhancement layer that do not overlie said recess.

4. The method according to claim 1, further comprising forming a second enhancement layer that overlies said upper surface of said conductive line, said second enhancement layer having substantial magnetic permeability or substantial dielectric permitivity or both substantial magnetic permeability and substantial dielectric permitivity.

5. The method according to claim 1, wherein said recess insulating layer is formed on a first insulating layer having a top surface and a bottom surface.

6. The method according to claim 5, wherein said first insulating layer includes at least one via extending there through from the top surface of said first insulating layer to the bottom surface said first insulating layer, and a conductive plug fills said via.

7. The method according to claim 6, wherein said bottom surface of said recess includes a top surface of said conductive plug.

8. A method of fabricating a passive transmission line element, comprising:
sequentially depositing an enhancement layer and a conductive layer material on a base structure that includes a bottom surface, a top surface, and at least one recess having a bottom recess surface and sidewalls, to provide a precursor structure having a top surface, said enhancement layer having substantial magnetic permeability or substantial dielectric permitivity or both substantial magnetic permeability and substantial dielectric permitivity; and
etching over the entire top surface of said precursor structure to completely remove said conductive layer material from regions that do not overlie said at least one recess to provide at least one conductive line respectively disposed in said at least one recess, and each at least one conductive line having a respective top surface that is disposed over and does not extend laterally beyond its corresponding said at least one recess, each of said at least one passive transmission line element comprising a respective said at least one conductive line and a corresponding portion of said enhancement layer that overlies the corresponding at least one recess and that surrounds sides and bottom of the respective conductive line.

9. The method according to claim 8, wherein said etching includes chemical-mechanical polishing.

10. A method for fabricating a passive transmission line device in an integrated circuit, the method comprising:
providing an insulating layer;
using a damascene process to form said passive transmission line device in said insulating layer, said passive transmission line device comprising a conductive line and a first enhancement layer, said conductive line embedded in said first enhancement layer that covers the bottom surface and sidewalls of a recess formed in said insulating layer during the damascene process, said first enhancement layer having substantial magnetic permeability or substantial dielectric permitivity or both substantial magnetic permeability and substantial dielectric permitivity.

11. An integrated circuit device, comprising:
an insulating layer that includes a recess having a bottom surface and walls; and
a passive transmission line device comprising a conductive line and a first enhancement layer, said first enhancement layer disposed over said bottom surface and said walls of said insulating layer, said conductive line embedded in said first enhancement layer that is formed on, said first enhancement layer having substantial magnetic permeability or substantial dielectric permitivity or both substantial magnetic permeability and substantial dielectric permitivity.

12. The integrated device at claim 11, wherein said method of forming a passive transmission line device in an integrated circuit, the said conductive line has an upper surface that does not extend laterally outside said recess.

13. The integrated device of claim 12, wherein the upper surface of said conductive line is substantially coplanar with said upper surface of said first insulating layer.

14. The integrated advice of claim 12, wherein the upper surface of said conductive line is substantially coplanar with an upper surface of said enhancement layer for portions of said enhancement layer that do not overlie said recess.

15. The integrated device of claim 12, further comprising forming a second enhancement layer that overlies said upper surface of said conductive line, said second enhancement layer having substantial magnetic permeability or substantial dielectric permitivity or both substantial magnetic permeability and substantial dielectric permitivity.

16. The integrated device of claim 12, wherein said recess insulating layer is formed on a first insulating layer having a top surface and a bottom surface.

17. The integrated device of claim 16, wherein said first insulating layer includes at least one via extending there through from the top surface of said first insulating layer to the bottom surface said first insulating layer, and a conductive plug fills said via.

18. The integrated device of claim 17, wherein said bottom surface of said recess includes a top surface of said conductive plug.

19. A passive transmission line element, comprising:
an enhancement layer and a conductive layer material sequentially depositing on a base structure that includes a bottom surface, a top surface, and at least one recess having a bottom recess surface and sidewalls, to provide a precursor structure having a top surface, said enhancement layer having substantial magnetic permeability or substantial dielectric permitivity or both substantial magnetic permeability and substantial dielectric permitivity; and wherein the entire top surface of said precursor structure etched to completely remove said conductive layer material from regions that do not overlie said at least one recess to provide at least one conductive line respectively disposed in said at least one recess, and each at least one conductive line having a respective top surface that is disposed over and does not extend laterally beyond its corresponding said at least one recess, each of said at least one passive transmission line element comprising a respective said at least one conductive line and a corresponding portion of said enhancement layer that overlies the corresponding at least one recess and that surrounds sides and bottom of the respective conductive line.

20. The passive transmission line element of claim 19, wherein said etch of said entire top surface includes chemical-mechanical polishing.

21. A passive transmission line device in an integrated circuit, comprising:
An insulating layer, wherein the passive transmission line is formed using a damascene process in said insulating layer, said passive transmission line device comprising a conductive line and a first enhancement layer, said conductive line embedded in said first enhancement layer that covers the bottom surface and sidewalls of a recess formed in said insulating layer during the damascene process, said first enhancement layer having substantial magnetic permeability or substantial dielectric permitivity or both substantial magnetic permeability and substantial dielectric permitivity.
